(19) United States
(12) Patent Application Publication
(10) Pub. No.: US 2019/0140126 A1
(43) Pub. Date: May 9, 2019

(54) LIGHT REFLECTIVE FILM AND MANUFACTURING METHOD THEREOF AND PHOTOVOLTAIC CELL MODULE

(71) Applicant: SUZHOU GOLDEN STAR ELECTRONIC TECHNOLOGY CO., LTD, Jiangsu (CN)

(72) Inventors: Liping ZHANG, Jiangsu (CN); Rui GAO, Jiangsu (CN); Jing DING, Jiangsu (CN)

(21) Appl. No.: 16/307,328

(22) PCT Filed: Jun. 13, 2018
(86) PCT No.: PCT/CN2018/091012

§ 371 Date: Dec. 5, 2018

(30) Foreign Application Priority Data
May 8, 2017 (CN) 201710319517.0

(51) Int. Cl. H01L 31/054; H01L 31/05; H01L 31/18; H01L 31/0216; G02B 5/04

(52) U.S. Cl. CPC H01L 31/0547; H01L 31/0508; G02B 5/045; H01L 31/02168; H01L 31/18

(57) ABSTRACT

A light reflective film, a processing method and a photovoltaic cell module. The vertex height of a prism and/or the bottom width of the prism change periodically to form a polyhedral structure, and the adjacent faces can present a mirror structure, so that the entire prism can reflect both morning and afternoon sunlight, which leads to improved reflection efficiency throughout the work period. In the prior art, the reflective surface of the straight triangular prism has a constant angle with respect to the axis of the working plane of a photovoltaic cell module, therefore, it only has high reflection efficiency for the sunlight at a certain time; the granular reflective micro-structure, such as a triangular pyramid, can be aligned with the sunlight on two sides thereof to reflect the sunlight in the morning and afternoon, but there are many blank areas between the granules.

### FIELD OF THE INVENTION

The present invention relates to a light reflective film, particularly to a light reflective film applied to a photovoltaic module, a manufacturing method thereof and a photovoltaic cell module.

### BACKGROUND OF THE INVENTION

The photovoltaic welding strip is used for connecting cells of a photovoltaic module, and plays an important role in electric conduction and concentration. In order to ensure reliable welding between the welding strip and the cells and prevent corrosion of the welding strip, the surface of the welding strip is coated with a tin layer. When the sunlight irradiates the surface of the welding strip, the smooth tin layer directly reflects the sunlight, and this part of the sunlight cannot be used by a cell panel, causing waste of light energy.

Some welding strips are provided with a stripe structure in their bodies to reflect light. However, as the base material of the welding strip is copper, the stripe structure hardly achieves a micro structure during processing, and the reflection effect is not ideal. Further, the strip structure may lead to uneven thickness of the surface tin layer, which easily cause fragmentation of the cells, and affect the production efficiency. In the prior art, micro-prisms and other micro-structures emerge to reflect the sunlight and improve the light conversion efficiency of photovoltaic modules. However, at present, the reflective film of a micro-prism structure such as a triangular prism structure has a fixed angle of reflection, whereas the trajectory of the sun is a 180° arc, so the reflective film of this kind has a shorter stay at its optimal reflection efficiency and which needs to be improved.

### SUMMARY OF THE INVENTION

In order to overcome the above deficiencies of the prior art, an objective of the present invention is to provide a photovoltaic reflective film which is simple in structure and low in cost and can fully utilize light.

In order to achieve the above objective, the technical solution adopted by the present invention to solve the technical problems is:

A light reflective film, having a flat body, wherein the body is provided with micro-structures for reflecting light, and the micro-structure includes at least one prism, and the prism has the following characteristics:

the vertex height of the prism and/or the bottom width of the prism change periodically.

Creatively, the vertex height of the prism and/or the bottom width of the prism change periodically to form a polyhedral structure, and the adjacent faces can present a mirror structure, so that the entire prism can reflect both morning and afternoon sunlight, which leads to improved reflection efficiency throughout the work period and overcomes the deficiencies of the prior art. In the prior art, the reflective surface of the straight triangular prism has a constant angle with respect to the axis of the working plane of a photovoltaic cell module, therefore, it only has high reflection efficiency for the sunlight at a certain time; the granular reflective micro-structure, such as a triangular pyramid, can be aligned with the sunlight on two sides thereof to reflect the sunlight in the morning and afternoon, but there are many blank areas between the granules, which hinders the reflection efficiency. In addition, processing such micro-structure is difficult and costly, which is not conductive to industrial application.

Further, the vertex height of the prism and/or the bottom width of the prism change periodically along a smooth curve.

Further, the cross section of the prism is one or a combination of two and more than two shapes selecting from triangle, semicircle, trapezoid, polygon, and a closed curve composed of multiple straight-line segments and curve segments.

Further, the bottom width of the prism changes with the vertex height of the prism;

when the vertex height of the prism increases, the bottom width of the prism increases synchronously; and when the vertex height of the prism reduces, the bottom width of the prism reduces synchronously.

Further, the changing curves of both the bottom width of the prism and the vertex height of the prism are sinusoidal.

Further, the curved surface angle α between the point A where the bottom width of the prism is largest and the point a where the width is smallest is 20°-80°, wherein a is the angle between the straight line T and the straight line Q, wherein T is the vertical line between the point a and the central axis of the prism, and Q is the tangent from the point a to the bottom curve between the point a and the point A. α is preferably 45°-65°.

Further, the cross section of the prism is a triangle with a vertex angle of 1°-150°, preferably 110°-130′, and most preferably 120°.

Further, the widest bottom width of the prism is 1-150 μm, preferably 40-60 μm,

Further, the bottom widths of the prism corresponding to the two adjacent highest points on the prism are different.

Further, the bottom widths in different sizes of each prism corresponding to the highest points of the prism are arranged at intervals, that is, the bottom widths of the prism corresponding to the two adjacent highest points are different.

Further, the bottom widths of the prism corresponding to the highest points of each prism have a large size and a small size, or three different sizes, or more than three different sizes.

Further, the corresponding highest points of each prism are on the same straight line, however, for two adjacent prisms, the bottom width corresponding to the highest point of one prism is different from the bottom width corresponding to the highest point of the other prism, and the bottoms with large widths are nested with the bottoms with small widths of the adjacent prism.

Further, the bottom widths of the prism corresponding to the two adjacent lowest points on the prism are different.

Further, the bottom widths in different sizes of each prism corresponding to the lowest points of the prism are arranged at intervals, that is, the bottom widths of the prism corresponding to the two adjacent lowest points are different.

Further, the corresponding lowest points of each prism are on the same straight line, however, for two adjacent prisms, the bottom width corresponding to the lowest point of one prism is different from the bottom width corresponding to the lowest point of the other prism, and the bottoms with large widths are nested with the bottoms with small widths of the adjacent prism.

The present invention further provides a processing method of the light reflective film, including the following steps:

step 1, making a mold by moving a cutter periodically back and forth on a uniformly rotating roller or a flat plate that moves at a constant speed to machine at least one groove with a periodically varying depth; and
step 2, imprinting a prismatic structure fitted with the groove on a reflective film by using the press roll or the planar template.

Further, the reflective film in step 2 includes a flat body, and a colloidal layer or reflective material layer laminated on the flat body.

Alternatively, the method further includes step 3 of making a reflective layer on the colloidal layer imprinted with the prismatic structure.

The present invention further provides a photovoltaic cell module, including a plurality of cells, a welding strip for connecting the cells and a light reflective film, wherein the photovoltaic reflective film is arranged on the upper surface of the welding strip or in gap regions between the cells, and the photovoltaic reflective film may also be simultaneously arranged on the upper surface of the welding strip and in gap regions between the cells, and the length direction of the photovoltaic reflective film is parallel to the length direction of the welding strip and the length direction of the gap regions.

By adopting the above preferred solution, the reflective film is arranged at a spatial position where light is not utilized in the photovoltaic module, and the light is reflected to the surface of the cells and converted into electrical energy, so that the power generated by the photovoltaic module is increased.

### BRIEF DESCRIPTION OF THE DRAWINGS

In order to describe the technical solutions in the embodiments of the present invention or in the prior art more clearly, the following briefly introduces the accompanying drawings required for describing the embodiments or the prior art. Apparently, the accompanying drawings in the following description show only some embodiments of the present invention, and a person of ordinary skill in the art may still derive other drawings from these accompanying drawings without creative efforts.

FIG. 1 is a schematic diagram according to an embodiment of the present invention;

FIG. 2 is a schematic diagram of a prism according to the present invention;

FIG. 3 is a schematic diagram in the prior art;

FIG. 4 and FIG. 5 are schematic diagrams of a product application according to the present invention.

### DETAILED DESCRIPTION OF THE EMBODIMENTS

A clear and complete description will be made to the technical solutions in the embodiments of the present invention below in combination with the accompanying drawings in the embodiments of the present invention. Apparently, the embodiments described are only part of the embodiments of the present invention, not all of them. All other embodiments obtained by a person of ordinary skill in the art based on the embodiments of the present invention without creative efforts shall fall within the protection scope of the present invention.

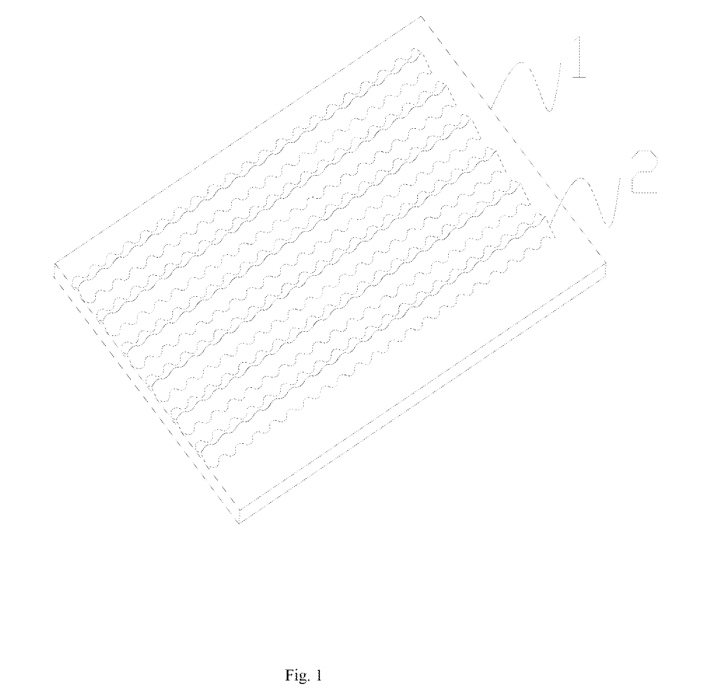

In order to achieve the objective of the present invention, as shown in FIG. 1, a light reflective film includes a flat body 1, the body 1 is provided with micro-structures for reflecting light, each micro-structure includes at least one prism 2, and the prism 2 has the following characteristic:

the vertex height of the prism and/or the bottom width of the prism change periodically.

FIG. 1 shows an example that the vertex height of the prism and the bottom width of the prism change periodically at the same time. Other structures are easy to understand and no illustration is given.

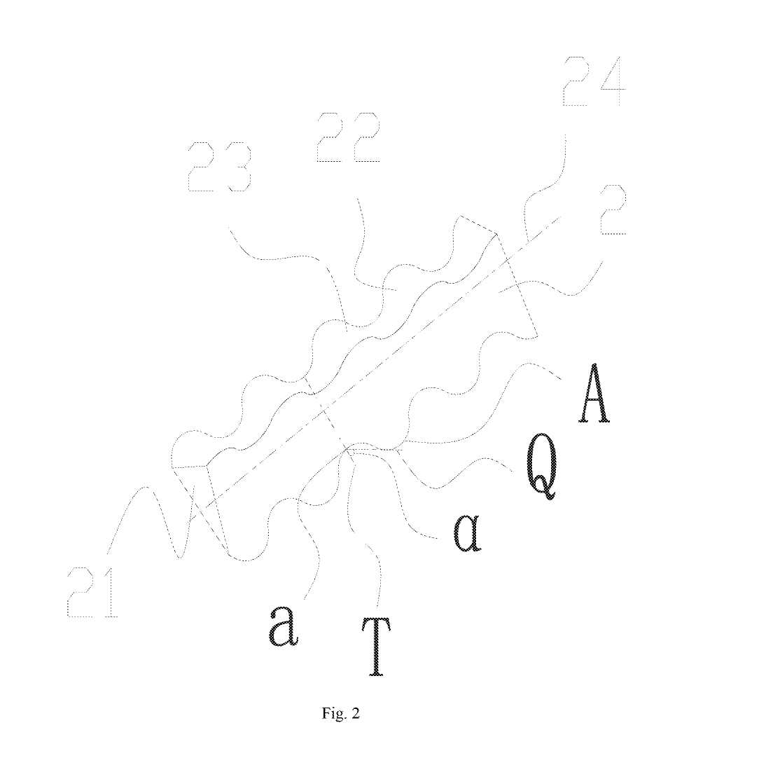

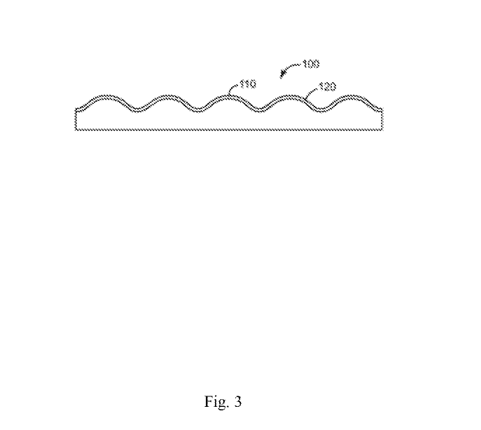

Creatively, according to the present invention, the vertex height of the prism 2 and/or the bottom width of the prism 2 change periodically to form a polyhedral structure, and the adjacent faces can be mirrored to each other (e.g., adjacent curved surfaces 23 and 22 in FIG. 2), so that the entire prism 2 can reflect the both morning and afternoon sunlight, which leads to improved reflection efficiency throughout the work period, and overcomes the deficiencies of the prior art. In the prior art, the reflective surface of the straight triangular prism has a constant angle with respect to the axis of the working plane of a photovoltaic cell module, therefore, it only has high reflection efficiency for the sunlight at a certain time; the granular reflective micro-structure, such as a triangular pyramid, can be aligned with the sunlight on two sides thereof to reflect the sunlight in the morning and afternoon, but there are many blank areas between the granules, which hinders the reflection efficiency. In addition, processing such micro-structure is difficult and costly, which is not conductive to industrialized application. The research on improving the utilization efficiency of light has never stopped. For example, FIG. 3 shows a proposed scheme of the utility patent publication No. US20160172518A1 filed by the well-known 3M INNOVATIVE PROPERTIES COMPANY. In FIG. 3, the original triangular prism is changed into a similar semi-cylinder, and the plane reflecting surface of the original triangular prism is changed into an arc surface. The single reflection angle is changed into to a multi-reflection angle in the direction perpendicular to the long axis of the reflective micro-structure, but the reflection angle does not change in the non-perpendicular direction as it is identical to other existing technologies, where any cross section of the reflective micro-structure is uniform. Other existing technologies are mostly similar fine tuning and exploration on applications at different locations in photovoltaic cell modules. It can be seen that due to the constraint of the existing technical ideas, every small change requires arduous efforts. It cannot be considered with hindsight that such a change is easily conceivable, and may be clearly derived from the technical development track of patent applications in this field. Therefore, the technical solution proposed by the present invention has prominent substantive characteristics and significant progress.

In some embodiments, the vertex height of the prism and/or the bottom width of the prism change periodically according to a smooth curve. In this way, it is not only beneficial to increase the processing speed, but also makes the light reflection angle more diverse and increases the coverage of the reflected light.

In practical applications, the cross section of the prism is one or a combination of two and more than two shapes selecting from triangle, semicircle, trapezoid, polygon, and a closed curve composed of multiple straight-line segments and curve segments. Preferably, the bottom width of the prism changes with the vertex height of the prism. When the vertex height of the prism increases, the bottom width of the prism increases synchronously. When the vertex height of the prism reduces, the bottom width of the prism reduces synchronously.

In a special case, the changing curves of both the bottom width of the prism and the vertex height of the prism are sinusoidal.

As shown in FIG. 2, taking into account both the sunlight reflection efficiency in different regions and in the morning and afternoon, the curved surface angle α between the point A where the bottom width of the prism is largest and the point a where the width is smallest is within the range of 20°-80°, wherein a is the angle between the straight line T and the straight line Q, wherein T is the vertical line between the point a and the central axis of the prism, and Q is the tangent from the point a to the bottom curve between the point a and the point A. α is preferably 45°-65°. That is, when the angle α shown in FIG. 2, for example, is 20° or 45° or 50° or 65° or 80°, the reflection efficiency of the sunlight in a certain region may be the highest. Accordingly, the reflection efficiency can be conveniently controlled by adjustments on the rotating speed or advancing speed of a mold during machining and the stroke and speed of feed and retraction of a cutter. Further adjustment can be achieved by changing the shape of the tool as required. In this way, the change of the curved surface of the reflecting surface can be easily controlled, adjusted and machined, which facilitates large-scale production. For applications in the regions of different dimensions, adjustments can be made conveniently. In addition to the sunlight reflection efficiency at different time intervals in the morning and afternoon, the mirror surface that changes periodically also improves the coverage of the reflected sunlight with multi-angle reflection, so that the reflected light is not concentrated on the limited zone of the cells. As a general choice, the angle α may be 45° or 65°.

In practical applications, the cross section of the prism may be a triangle with a vertex angle of 1°-150°, preferably 110°-130°, and most preferably 120°.

In practical applications, the widest bottom width of the prism is 1-150 μm, e.g., 5 μm, 10 μm, 20 μm . . . 70 μm, 80 μm, 90 μm, 100 μm, etc., preferably 40-60 μm, e.g., 40 μm, 50 μm or 60 μm.

In practical applications, the prism may also be set according to the following rules: The bottom widths of the prism corresponding to the two adjacent highest points on the prism are different. In this way, the sunlight reflection angle at different positions of the prism can be conveniently adjusted by adjusting the bottom widths of the prism corresponding to the highest points of the prism, so that the position distribution of sunlight reflection can be accurately controlled, and the utilization efficiency of sunlight can be further improved.

For example, the bottom widths in different sizes of each prism corresponding to the highest points of the prism are arranged at intervals, that is, the bottom widths of the prism corresponding to the two adjacent highest points are different. The bottom widths of the prism corresponding to the highest points may have two sizes: large and small, such as 60 μm and 40 μm, and may also have three sizes, such as 40 μm, 50 μm and 60 μm, and of course, may have more than three sizes, as required.

Further, the corresponding highest points of each prism are on the same straight line. However, for two adjacent prisms, the bottom width corresponding to the highest point of one prism is different from the bottom width corresponding to the highest point of the other prism, and the bottoms with large widths are nested with the bottoms with small widths of the adjacent prism. Thus, the density of the prisms can be improved, the number of the prisms can be increased and the reflection and utilization of sunlight can be improved.

Similarly, the bottom widths of the prism corresponding to the lowest points of the prism may also be arranged according to this rule: the bottom widths of the prism corresponding to the two adjacent lowest points on the prism are different. In this way, the sunlight reflection angle at different positions of the prism can be conveniently adjusted by adjusting the bottom widths of the prism corresponding to the lowest points of the prism, so that the position distribution of sunlight reflection can be accurately controlled, and the utilization efficiency of sunlight can be further improved.

For example, the bottom widths in different sizes of each prism corresponding to the lowest points of the prism are arranged at intervals, that is, the bottom widths of the prism corresponding to the two adjacent lowest points are different. The bottom widths of the prism corresponding to the lowest points may have two sizes: large and small, such as 20 μm and 10 μm, may also have three sizes, such as 30 μm, 20 μm and 10 μm, and of course, may have more than three sizes, as required.

Further, the corresponding lowest points of each prism are on the same straight line. However, for two adjacent prisms, the bottom width corresponding to the lowest point of one prism is different from the bottom widths corresponding to the lowest point of the other prism, and the bottom with large widths are nested with the bottoms with small widths of the adjacent prism. Thus, the density of the prisms can be improved, the number of the prisms can be increased and the reflection and utilization of sunlight can be improved.

The present invention further provides a processing method of the light reflective film, including the following steps:

step 1, making a mold by moving a cutter periodically back and forth on a uniformly rotating roller or a flat plate that moves at a constant speed to machine at least one groove with a periodically varying depth; and
step 2, imprinting a prismatic structure fitted with the groove on a reflective film by using the press roll or the planar template.

Further, the reflective film in step 2 includes a flat body, and a colloidal layer or reflective material layer laminated on the flat body.

Moreover, the method further includes step 3 of making a reflective layer on the colloidal layer imprinted with the prismatic structure.

The flat body may be made of a flexible film material, and the material for the colloidal layer may be found in the prior art, so these materials are not redundantly described here. The method described above is only based on a product with a two-layer structure. A product with a multi-layer structure can also be produced using this method. The only difference is that the multi-layer flat body is manufactured first, or other functional layer is compounded in the subsequent process.

The present invention further provides a photovoltaic cell module, including a plurality of cells, a welding strip for connecting the cells and the light reflective film in the foregoing example, wherein the photovoltaic reflective film is arranged on the upper surface of the welding strip or in gap regions between the cells, and the photovoltaic reflective film may also be simultaneously arranged on the upper surface of the welding strip and in gap regions between the cells, and the length direction of the photovoltaic reflective film is parallel to the length direction of the welding strip and the length direction of the gap regions.

By adopting the above preferred solution, the reflective film is arranged at a spatial position where light is not utilized in the photovoltaic module, and the light is reflected to the surface of the cells and converted into electrical energy, so that the power generated by the photovoltaic module is increased.

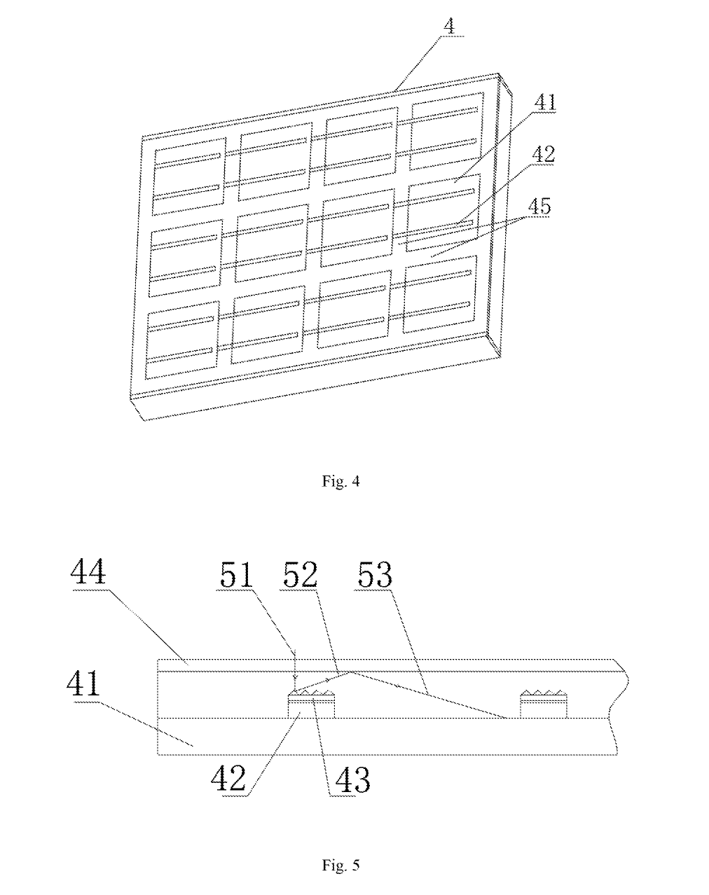

FIG. 4 shows an application of the photovoltaic reflective film. The photovoltaic reflective film is applied to a photovoltaic module 4 to improve the power of the photovoltaic module; the photovoltaic module 4 includes a plurality of cells 41 and a welding strip 42 for connecting the cells, the photovoltaic reflective film is arranged on the upper surface of the welding strip 42, the photovoltaic reflective film may also be arranged in gaps 45 between the cells 41 or simultaneously arranged at the two positions; and the length direction of the photovoltaic reflective film is parallel to the length direction of the gaps 45, and the length direction of the photovoltaic reflective film is also parallel to the length direction of the welding strip 42. The beneficial effect of the above technical solution is: the photovoltaic reflective film is arranged at a spatial position where light is not utilized in the photovoltaic module, and the light is reflected to the surface of the cells and converted into electrical energy, so that the power generated by the photovoltaic module is increased.

The principle of reflecting light in the photovoltaic module according to the present invention will be illustrated below referring to FIG. 5. The photovoltaic reflective film 43 of the present invention is attached to the surface of the welding strip 42. The incident light 51 (sunlight) is incident on the reflective layer of the photovoltaic reflective film 43 through a glass sheet 44 and changes its path to a reflected light 52 through reflection, then the light is totally reflected through the surface of the glass sheet 44 to change the path to form total reflected light 53, which finally reaches the cells 41, and the light energy is absorbed and converted into electric energy.

The present invention brings the following advantages:

1. Processing and large-scale production are facilitated, and the processing cost is low.
2. For different dimensional regions, the angle α of the reflection surface can be easily adjusted.
3. For the entire sunshine time, the reflectivity is improved for different incident angles of the sunlight, and the power generated by the solar photovoltaic module is improved.

The foregoing embodiments are merely to illustrate the technical concept and characteristics of the present invention, and aim to allow those of ordinary skill in the art to understand the content of the present invention and implement the same, but the scope of the present invention is not limited thereto. All equivalent changes or modifications made according to the essence of the present invention should fall into the protection scope of the present invention.

1. A light reflective film, comprising a flat body, wherein the body is provided with micro-structures for reflecting light, and the micro-structure comprises at least one prism, and the prism has the following characteristic:
the vertex height of the prism and/or the bottom width of the prism change periodically.

2. The light reflective film according to claim 1, wherein the vertex height of the prism and/or the bottom width of the prism change periodically along a smooth curve.

3. The light reflective film according to claim 1, wherein the cross section of the prism is one or a combination of two and more than two shapes selecting from triangle, semicircle, trapezoid, polygon, and a closed curve composed of multiple straight-line segments and curve segments.

4. The light reflective film according to claim 1, wherein the bottom width of the prism changes with the vertex height of the prism; when the vertex height of the prism increases, the bottom width of the prism increases synchronously; and when the vertex height of the prism reduces, the bottom width of the prism reduces synchronously.

5. The light reflective film according to claim 4, wherein the changing curves of both the bottom width of the prism and the vertex height of the prism are sinusoidal.

6. The light reflective film according to claim 4, wherein the curved surface angle α between the point A where the bottom width of the prism is largest and the point a where the width is smallest is 20°-80°, a is the angle between the straight line T and the straight line Q, wherein T is the vertical line between the point a and the central axis of the prism, Q is the tangent from the point a to the bottom curve between the point a and the point A, and a is preferably 45°-65°.

7. The light reflective film according to claim 6, wherein the cross section of the prism is a triangle with a vertex angle of 1°-150°, preferably 110°-130°, and most preferably 120°.

8. The light reflective film according to claim 6, wherein the widest bottom width of the prism is 1-150 μm, preferably 40-60 μm.

9. The light reflective film according to claim 1, wherein the bottom widths of the prism corresponding to the two adjacent highest points on the prism are different.

10. The light reflective film according to claim 1, wherein the bottom widths in different sizes of each prism corresponding to the highest points of the prism are arranged at intervals, that is, the bottom widths of the prism corresponding to the two adjacent highest points are different.

11. The light reflective film according to claim 10, wherein the bottom widths of the prism corresponding to the highest points of each prism have a large size and a small size, or three different sizes, or more than three different sizes.

12. The light reflective film according to claim 1, wherein the corresponding highest points of each prism are on the same straight line, however, for two adjacent prisms, the bottom width corresponding to the highest point of one prism is different from the bottom width corresponding to the highest point of the other prism, and the bottoms with large widths are nested with the bottoms with small widths of the adjacent prism.

13. The light reflective film according to claim 12, wherein the bottom widths of the prism corresponding to the two adjacent lowest points on the prism are different.

14. The light reflective film according to claim 1, wherein the bottom widths in different sizes of each prism corresponding to the lowest points of the prism are arranged at intervals, that is, the bottom widths of the prism corresponding to the two adjacent lowest points are different.

15. The light reflective film according to claim 1, wherein the corresponding lowest points of each prism are on the same straight line, however, for two adjacent prisms, the bottom width corresponding to the lowest point of one prism is different from the bottom width corresponding to the lowest point of the other prism, and the bottoms with large widths are nested with the bottoms with small widths of the adjacent prism.

16. A processing method of the light reflective film, comprising the following steps:
step 1, making a mold by moving a cutter periodically back and forth on a uniformly rotating roller or a flat plate that moves at a constant speed to machine at least one groove with a periodically varying depth; and
step 2, imprinting a prismatic structure fitted with the groove on a reflective film by using the press roll or the planar template.

17. The processing method of the light reflective film according to claim 16, wherein the reflective film in step 2 includes a flat body, and a colloidal layer or reflective material layer laminated on the flat body, or the method further comprises step 3 of making a reflective layer on the colloidal layer imprinted with the prismatic structure.

18. A photovoltaic cell module, comprising a plurality of cells, a welding strip for connecting the cells and a light reflective film, wherein the photovoltaic reflective film is arranged on the upper surface of the welding strip or in gap regions between the cells, and the photovoltaic reflective film may also be simultaneously arranged on the upper surface of the welding strip and in gap regions between the cells, and the length direction of the photovoltaic reflective film is parallel to the length direction of the welding strip and the length direction of the gap regions.
